(19) United States
(12) Patent Application Publication
(10) Pub. No.: US 2017/0301815 A1
(43) Pub. Date: Oct. 19, 2017

(54) SOLAR-CELL MODULE

(71) Applicant: Panasonic Intellectual Property Management Co., Ltd., Osaka (JP)

(72) Inventors: Toshio YAGIURA, Shiga (JP); Hiroyuki KANNOU, Osaka (JP); Yoshihide KAWASHITA, Osaka (JP); Ryoji NAITO, Osaka (JP); Saori YAMASHITA, Osaka (JP)

(21) Appl. No.: 15/477,755

(22) Filed: Apr. 3, 2017

Related U.S. Application Data
(63) Continuation of application No. 14/993,666, filed on Jan. 12, 2016.
Application No. 14/993,666 is a continuation of application No. PCT/JP2014/003618, filed on Jul. 8, 2014.

(30) Foreign Application Priority Data
Jul. 19, 2013 (JP) 2013-151010

(51) Int. Cl. H01L 31/05; H01L 31/054; H01L 31/048; H01L 31/18

(52) U.S. Cl. CPC H01L 31/0508; H01L 31/1864; H01L 31/0547; H01L 31/048

(57) ABSTRACT

This solar-cell module and method is provided with a plurality of solar cells and a connecting member that connects the light-receiving-surface side of one solar cell to the back-surface side of an adjacent solar cell. Said connecting member comprises a conductor that includes the following: a flat section laid out on the light-receiving-surface side of the aforementioned one solar cell, a flat section laid out on the back-surface side of the other solar cell, and a middle section that joins said flat sections to each other. The hardness of a boundary region between one of the flat sections and the middle section is no more than 1.25 times the hardness of that flat section.

### CROSS-REFERENCE TO RELATED APPLICATIONS

The present application is a continuation application of U.S. patent application Ser. No. 14/993,666, filed on Jan. 12, 2016, the entire contents of which are incorporated herein by reference. The Ser. No. 14/993,666 application is the bypass continuation of Application No. PCT/JP2014/003618, filed Jul. 8, 2014, which is incorporated herein by reference and which claimed priority to Japanese Patent Application No. 2013-151010 filed on Jul. 19, 2013. The present application likewise claims priority under 35 U.S.C. §119 to Japanese Patent Application No. 2013-151010 filed on Jul. 19, 2013, the entire content of which is also incorporated herein by reference.

### BACKGROUND

### Technical Field

The present invention relates to a solar cell module, and in particular, to a solar cell module in which a plurality of solar cells are connected to each other using a connecting member.

### Related Art

A solar cell module is formed by connecting a plurality of solar cells to each other by a plurality of connecting members.

Patent Document 1 discloses that, in a solar cell module in which solar cells adjacent to each other are connected by a connecting member, by providing a depression-projection portion on the connecting member, it becomes possible to prevent occurrence of cell crack and electrode detachment in a manufacturing process of the solar cell module.

### RELATED ART REFERENCE

### Patent Document

[Patent Document 1] JP 2005-302902 A

An advantage of the present invention is that, in a solar cell module, fatigue breakdown caused by a difference in thermal expansion coefficients between a surface protective member, such as glass, and the solar cell is suppressed.

### SUMMARY

According to one aspect of the present invention, there is provided a solar cell module comprising: a plurality of solar cells; a connecting member that connects, of adjacent solar cells, a light receiving surface side of the solar cell on one side and a back surface side of the solar cell on the other side; and a protective member on the light receiving surface side and a protective member on the back surface side that are placed via respective sealing members on the light receiving surface side and the back surface side, respectively, of the solar cells connected to each other by the connecting member, wherein the connecting member is formed from a conductor comprising: a first flat portion placed on the light receiving surface side of the solar cell on the one side; a second flat portion placed on the back surface side of the solar cell on the other side; and an intermediate portion connecting the first flat portion and the second flat portion, and, in the connecting member, a hardness of a boundary region between the first flat portion or the second flat portion and the intermediate portion is less than or equal to 1.25 times a hardness of the first flat portion or the second flat portion.

### Advantageous Effect

According to the solar cell module of various aspects of the present invention, because a difference in hardness is small in the connecting member, fatigue breakdown can be suppressed.

### BRIEF DESCRIPTION OF THE DRAWINGS

FIG. 1 is a cross sectional diagram of a solar cell module according to a preferred embodiment of the present invention.

FIG. 2 is a partial enlarged diagram of FIG. 1, FIG. 2A being an enlarged view with the magnifications in a layering direction and an extension direction being the same; FIG. 2B being a schematic view in which the thickness direction is enlarged more compared to the extension direction, and FIGS. 2C and 2D being cross sectional diagrams cut in a plane perpendicular to a direction of extension of a connecting member.

FIG. 3 is a diagram showing a method of bending a connecting member in related art, FIG. 3A being a side view along a direction of extension of the connecting member, and FIGS. 3B and 3C being cross sectional diagrams cut in a plane perpendicular to a direction of extension of the connecting member.

FIG. 4 is a diagram showing a hardness measurement in a bent connecting member of FIG. 3, FIG. 4A being a schematic diagram showing locations where the hardness measurements are taken, and FIGS. 4B, 4C, and 4D being diagrams showing hardness distributions at different measurement locations along a thickness direction of the connecting member.

FIG. 5 is a diagram comparing probability of occurrence of fatigue breakdown in a temperature cycle for a connecting member of related art and a connecting member before a bending formation step.

### DETAILED DESCRIPTION

A preferred embodiment of the present invention will now be described in detail with reference to the drawings. Materials, thicknesses, sizes, numbers of solar cells, or the like described below are exemplary for the purpose of description, and may be suitably changed according to the specification of the solar cell module. In the following, corresponding elements in all drawings are assigned the same reference numerals, and will not be repeatedly described.

### (Structure of Solar Cell Module 10)

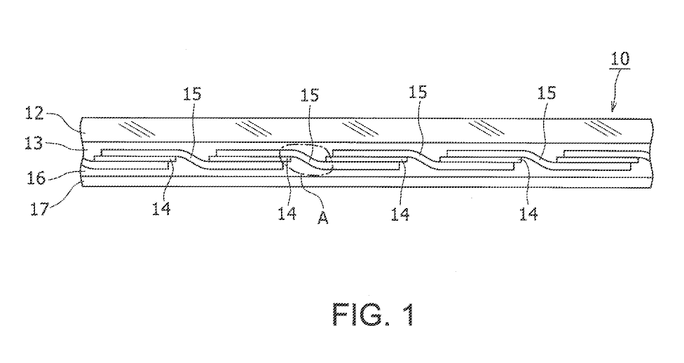

FIG. 1 is a cross sectional diagram of a solar cell module 10. The solar cell module 10 comprises, from a light receiving surface side toward a back surface side, a protective member 12, a sealing member 13, a plurality of solar cells 14 and a plurality of connecting members 15 which connect the solar cells 14 to each other, a sealing member 16, and a protective member 17, in this order. In the following, a direction of arrangement of the members from the light receiving surface side toward the back surface side will be referred to as a layering direction. A light receiving surface is a surface through which the light primarily enters, and a back surface is a surface opposing the light receiving surface.

The protective member 12 on the light receiving surface side is a transparent plate or sheet through which light can be taken in from the outside. As the protective member 12, a member having a light transmissive characteristic can be employed such as a glass plate, a resin plate, a resin sheet, or the like.

The sealing member 13 on the light receiving surface side is a member that has a role of a shock cushioning member for the plurality of solar cells 14 connected to each other by the connecting members 15, and has a function to prevent intrusion of contamination substances, foreign substances, moisture, or the like. A material of the sealing member 13 is selected in consideration of thermal endurance, adhesion characteristic, flexibility, molding characteristic, endurance, or the like. For the sealing member 13, in order to take in light from the outside, a transparent encapsulant, which has a maximum possible transparency and which transmits the entering light without absorbing or reflecting the light, is employed. For example, a polyethylene-based olefin resin, ethylene vinyl acetate (EVA), or the like is employed. Other than the EVA, an EEA, a PVB, a silicone-based resin, a urethane-based resin, an acryl-based resin, an epoxy-based resin, or the like may be employed.

Structures or the like of the solar cell 14 and the connecting member 15 will be described later.

The sealing member 16 on the back surface side is a member having a function similar to that of the sealing member 13 on the light receiving surface side. For the sealing member 16, an encapsulant having a structure similar to that for the sealing member 13 may be used, or a colored encapsulant having a suitable reflectivity may be employed. As the colored encapsulant having suitable reflectivity, a structure may be employed in which an inorganic pigment such as titanium oxide or zinc oxide is added as an additive for coloring the white color to the above-described colorless, transparent encapsulant.

For the protective member 17 on the back surface side, a non-transparent plate or sheet may be employed. Specifically, in addition to resin sheets such as fluorine-based resin, polyethylene terephthalate (PET), or the like, a layered sheet in which aluminum foil is sandwiched by these resin sheets may be employed. Alternatively, as the protective member 17, a colorless, transparent sheet may be employed.

### (Structures of Solar Cell 14 and Connecting Member 15)

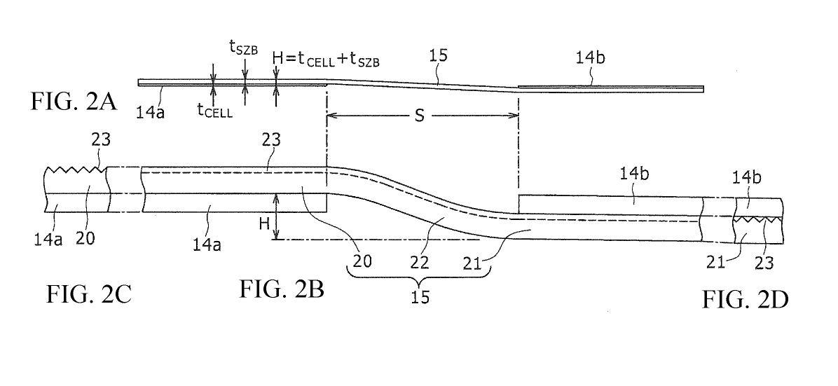

Next, structures of the solar cell 14 and the connecting member 15 will be described with reference to FIG. 2. FIG. 2 is a diagram enlarging an A part of FIG. 1, and shows a connection of two adjacent solar cells 14 by the connecting member 15. In the following, a direction which is perpendicular to the layering direction and in which the plurality of solar cells 14 are connected by the connecting member 15 and extend will be referred to as an extension direction, and a direction perpendicular to the layering direction and orthogonal to the extension direction will be referred as a width direction. A thickness direction is the same direction as the layering direction, and a thickness is the dimension, that is, a length, in the layering direction.

FIG. 2A is an enlarged view in which magnifications in the layering direction and the extension direction are set equal to each other. In the drawing, a space between two solar cells 14a and 14b adjacent in the extension direction is shown as S, the thickness of the solar cells 14a and 14b is shown as t_{CELL}, the thickness of the connecting member 15 is shown as t_{SZB}, and a step in the layering direction of the connecting member 15 when the connecting member 15 is placed from the light receiving surface side of the solar cell 14a to the back surface side of the solar cell 14b is shown by H. FIGS. 2B, 2C, and 2D are schematic diagrams enlarging the layering direction by approximately 5 times compared to the extension direction. FIG. 2B is a cross sectional diagram corresponding to FIG. 2A, and FIGS. 2C and 2D are side views.

Although not shown in FIG. 1, the solar cell 14 comprises a photoelectric conversion unit, a light receiving surface electricity collecting electrode, and a back surface electricity collecting electrode.

The photoelectric conversion unit receives light such as the solar light, and generates photogenerated carriers, that is, holes and electrons. The photoelectric conversion unit has a substrate of a semiconductor material such as, for example, crystalline silicon (c-Si), gallium arsenide (GaAs), indium phosphide (InP), or the like. The structure of the photoelectric conversion unit is a pn junction in a wide sense. For example, a hetero junction of an n-type monocrystalline silicon substrate and amorphous silicon may be employed. In this case, over the substrate on the light receiving surface side, an i-type amorphous silicon layer, a p-type amorphous silicon layer doped with boron (B) or the like, and a transparent conductive film (TCO) formed of a transparent conductive oxide such as indium oxide (In₂O₃) are layered, and on the back surface side of the substrate, an i-type amorphous silicon layer, an n-type amorphous silicon layer doped with phosphorous (P) or the like, and a transparent conductive film are layered, to form a double-surface generation type structure.

The photoelectric conversion unit may have structures other than the above-described structure, so long as the photoelectric conversion unit has a function to convert light such as the solar light into electricity. For example, the photoelectric conversion unit may have a structure having a p-type polycrystalline silicon substrate, an n-type diffusion layer formed on the light receiving surface side of the substrate, and an aluminum metal film formed on the back surface side of the substrate.

The light receiving surface electricity collecting electrode and the back surface electricity collecting electrode are electrodes for connection, and the connecting member 15 is connected thereto. One solar cell comprises, for example, three light receiving surface electricity collecting electrodes over the light receiving surface, and three back surface electricity collecting electrodes on the back surface side. The light receiving surface electricity collecting electrodes are arranged along the width direction of the solar cell 14, and extend in the extension direction. The back surface electricity collecting electrodes are similarly placed. The widths of the light receiving surface electricity collecting electrode and the back surface electricity collecting electrode are preferably about 1.5 mm to 3 mm, and the thicknesses are preferably about 20 μm to 160 μm. In addition, over the light receiving surface and the back surface of the solar cell 14, a plurality of narrow line electrodes orthogonal to the light receiving surface electricity collecting electrode and the back surface electricity collecting electrode, respectively, may be formed. The narrow line electrodes are electrically connected to the light receiving surface electricity collecting electrode and the back surface electricity collecting electrode.

The connecting member 15 is a conductive member which connects adjacent solar cells 14. The connecting member 15 is connected, of the adjacent solar cells 14, to three light receiving surface electricity collecting electrodes over the light receiving surface of the solar cell 14a on one side, and to three back surface electricity collecting electrodes over the back surface of the solar cell 14b on the other side. The connecting member 15 and the light receiving surface electricity collecting electrode and the back surface electricity collecting electrode are connected via an adhesive. The width of the connecting member 15 is set to a value about the same as or slightly larger than those of the light receiving surface electricity collecting electrode and the back surface electricity collecting electrode. For the connecting member 15, a thin plate formed from a conductive metal material such as copper is used. Depending on specific cases, a stranded wire shape may be employed in place of the thin plate shape. As the conductive material, in addition to copper, silver, aluminum, nickel, tin, gold, or alloys of these metals may be employed.

As shown in FIG. 2, the connecting member 15 may have, as the surfaces on both sides overlapping in the thickness direction, a flat surface for the surface on one side and a diffusion surface 23 having a depression-projection shape for the surface on the other side. The depression-projection shape is formed by a plurality of depression-projection grooves extending in a direction of extension of the connecting member 15. The diffusion surface 23 diffuse-reflects the light hitting the connecting member 15 of the light entering the light receiving surface side in the solar cell module 10, and re-reflects the light on the back surface side of the protective member 12 on the light receiving surface side. With such a configuration, the light which once hits the connecting member 15 can be directed to enter the light receiving surfaces of the solar cells 14a and 14b, and the light reception efficiency can be improved.

As the adhesive connecting the light receiving surface electrode and the back surface electrode of the solar cell 14 and the connecting member 15, in addition to solder, it is possible to use a thermosetting resin adhesive such as an acryl-based resin, a polyurethane resin having high flexibility, an epoxy-based resin, or the like. When an insulating resin adhesive is used as the adhesive, preferably, depressions and projections are formed over one or both of surfaces opposing each other of the connecting member 15 or the light receiving surface electricity collecting electrode, and the resin is suitably removed from the region between the connecting member 15 and the light receiving surface electricity collecting electrode, to achieve electrical connection. Alternatively, as the adhesive, a conductive adhesive in which conductive particles such as nickel, silver, gold-coated nickel, tin-plated copper, or the like are contained in the insulating resin adhesive may be employed. As the thickness of the adhesive is thin compared to the thickness of the connecting member 15, the display of the adhesive is omitted in the drawings.

As shown in FIG. 2B, the connecting member 15 has a flat portion 20 placed on the light receiving surface side of the solar cell 14a on one side, a flat portion 21 placed on the back surface side of the solar cell 14b on the other side, and an intermediate portion 22 connecting the flat portion 20 and the flat portion 21. A boundary region between the flat portion 20 and the intermediate portion 22 and a boundary region between the intermediate portion 22 and the flat portion 21 change smoothly without a clear point of deflection. In other words, a slope of a tangential line of the connecting member 15 in the cross sectional diagram changes continuously from the light receiving surface side of the solar cell 14a on the one side to the back surface side of the solar cell 14b on the other side, and does not have an inflection point where the slope becomes discontinuous.

In order to form one connecting member 15 in this manner and in the smoothly changing shape when the connecting member 15 is placed from the light receiving surface side of the solar cell 14a on the one side to the back surface side of the solar cell 14b on the other side, the connecting member 15 is not bent by pressurizing on a ridge line along the width direction of the tool, but rather, for example, is deformed by pressurizing the entirety of the member by a plane of the tool. In this manner, when the connecting member 15 is formed to smoothly change from the light receiving surface side of the solar cell 14a on the one side to the back surface side of the solar cell 14b on the other side, it becomes possible to suppress increasing hardness of a portion corresponding to the pressurized boundary region of the connecting member 15.

(Comparison with Related Art)

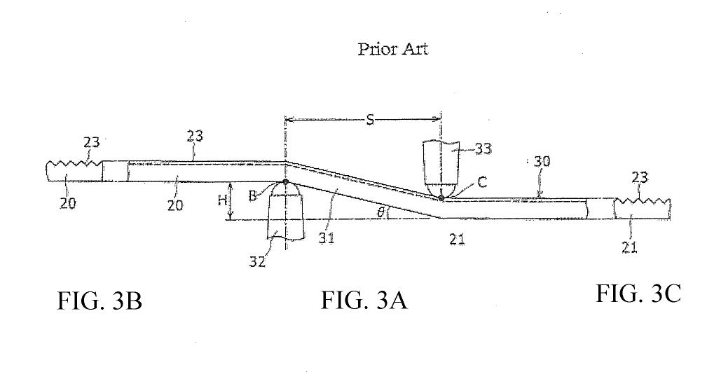

FIG. 3 is a diagram showing an example structure of a connecting member 30 in the related art, for comparison purposes. For the connecting member 30 in the related art, a structure is employed in which a diffusion surface 23 is formed, a conductor material of a long length which is cut in a predetermined width is formed in advance, and machining distortion or the like is removed by a thermal process. The long-length conductor material is wound in a reel form and stored for a time. At this stage, the connecting material has approximately a constant hardness over the entirety of the connecting material due the thermal process for removing machining distortion, and the hardness distribution is such that the hardness is uniform in a thickness direction, an extension direction, and a width direction of the connecting member 15.

Then, when the solar cell module 10 is manufactured, the conductor material is wound back from the reel, and is cut in a length necessary for connecting two adjacent solar cells 14a and 14b while shaping the conductor material in a straight shape. When the solar cells 14a and 14b are to have an approximate square shape with the length of one side being about 125 mm, the conductor material is cut in a length of about 250 mm.

Then, as shown in FIG. 3A, using two bending tools 32 and 33 placed to be distanced by S which is a spacing between two adjacent solar cells 14a and 14b, the conductor material is bent at boundary regions B and C on the cross sectional diagrams such that tanθ=H/S. As an example, when S/H=5, tanθ=H/S=0.2, and consequently, θ is about 10 degrees. Thus, the connecting member 30 of the related art is bent at the boundary region B between the flat portion 20 and the intermediate portion 22 with an angle of about 10 degrees, is bent in the opposite direction at the boundary region C between the intermediate portion 22 and the flat portion 21 with an angle of about 10 degrees, and a bent shape is formed.

In this manner, the connecting member 30 is formed as a bent member having two boundary regions B and C, and in this bent shape, the flat portion 20 is connected to the light receiving surface electricity collecting electrode of the solar cell 14a on the one side via an adhesive and the flat portion 21 is connected to the back surface electricity collecting electrode of the solar cell 14b on the other side via an adhesive.

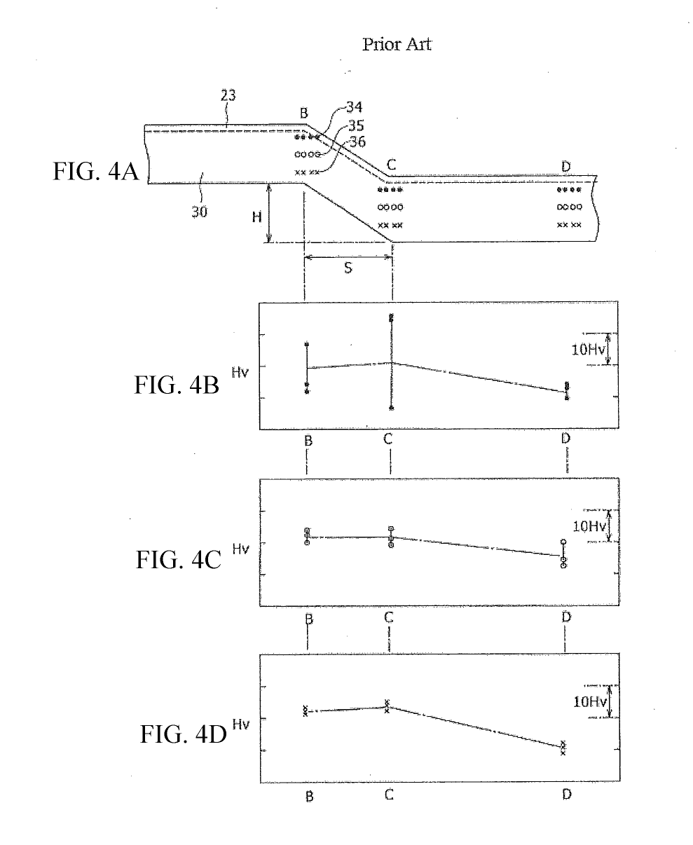

In the bending formation step, in the connecting member 30, a machining distortion occurs around the boundary regions B and C, and due to machining hardening of these regions, the hardness becomes high near the boundary regions B and C, and the hardness distribution of the connecting member 30 becomes non-uniform. FIG. 4 is a diagram showing a hardness measurement in the connecting member 30 of the related art.

The hardness measurement was performed using a microvickers hardness meter manufactured by Mitsutoyo and having a model number of HM-221. As the material of the connecting member 30 is copper, the measurement pressure was set to a value recommended by HM-221 as a value suited for hardness measurement of 60-80 Hv which is a standard microvickers hardness of copper.

FIG. 4A is a diagram corresponding to FIG. 3, and is a schematic diagram showing locations of the hardness measurement. B and C show locations corresponding to the boundary regions B and C of FIG. 3, and D shows a location on the flat portion 21 sufficiently distanced from the boundary region C along the extension direction. Here, the hardness measurement was performed at three measurement positions 34, 35, and 36 along the thickness direction of the connecting member 30 at each of the locations B, C, and D. The measurement position 34 is a position on a side near the diffusion surface 23 of the connecting member 30, the measurement position 35 is an approximately center position in the thickness direction of the connecting member 30, and the measurement position 36 is a position at a side near the flat surface which is on an opposite side of the diffusion surface 23 of the connecting member 30.

FIG. 4B is a diagram showing a hardness distribution at the measurement position 34. The horizontal axis represents a position along the extension direction of the connecting member 30, and the vertical axis represents the microvickers hardness. The vertical axis is shown with relative values, with one scale division representing a difference of 10 Hv in microvickers hardness. The hardness measurement was determined by, at the measurement position 34 of each of the locations B, C, and D, performing the hardness measurement four times while separating the measurement positions from each other, and calculating the average of the measured values. The hardness measurement was performed for three connecting members 30. In FIG. 4B, the averages of the microvickers hardness of three connecting member 30 at each of the locations of B, C, and D are shown.

Similarly, FIG. 4C is a diagram showing the hardness distribution at the measurement position 35, and FIG. 4D is a diagram showing the hardness distribution at the measurement position 36. In each diagram, the center values of variation of the hardness values of three connecting members 30 are connected by a dot-and-chain line, to show the difference in hardness of the locations B, C, and D.

As shown in these diagrams, the hardnesses of the locations corresponding to the boundary regions B and C are higher than the hardness at the flat portion 21. In the result of experiment, the hardness of the locations corresponding to the boundary regions B and C, on average, are values larger than 1.25 times the hardness of the flat portion 21 over the solar cells 14a and 14b. Between the locations corresponding to the boundary regions B and C, the hardness of the location corresponding to the boundary region C is higher than the hardness of the location corresponding to the boundary region B. In addition, the hardness of the location corresponding to the boundary region C in which the diffusion surface 23 contacts the surface of the solar cell 14b has a large variation among the three connecting members 30. It can be considered that these results have been obtained because the boundary region C was formed by pressurizing a projection of the depression-projection shape of the diffusion surface 23 with the bending tool 33 to bend the surface toward the light receiving surface side, and as a consequence, the machining distortion near the projection of the boundary region C became large and the hardness became high. The highest hardness value over the entire measurement appeared at this location corresponding to the boundary region C. In the experimental result, the hardness near the projection of the boundary region C is larger than 1.1 times the hardness near the depression of the boundary region C.

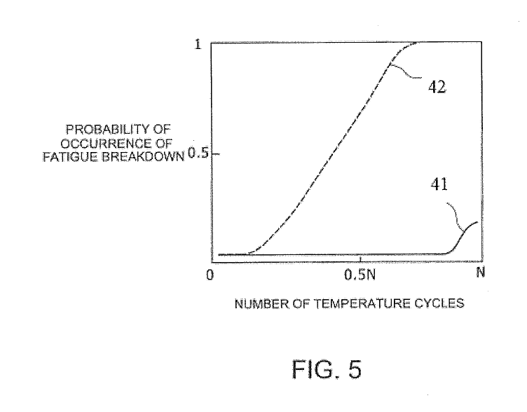

FIG. 5 is a diagram showing a result of checking a relationship between a difference in hardness in the connecting member and the probability of occurrence of fatigue breakdown in the solar cell module 10 in a temperature cycle test. The horizontal axis of FIG. 5 represents a number of temperature cycles and the vertical axis represents the probability of occurrence of the fatigue breakdown. The horizontal and vertical axes are both shown in a normalized manner. The temperature cycle was realized by changing the environmental temperature at −40° C. and +90° C. for the solar cell module 10.

FIG. 5 shows a characteristic line 41 of a sample having a uniform hardness over the entirety of the connecting material by the thermal process for removing the machining distortion, such as the connecting member 15 before the bending formation step, and a characteristic line 42 of a sample having the hardness of the locations corresponding to the boundary regions B and C which are on average greater than 1.25 times the hardness of the flat portion 21 over the solar cells 14a and 14b such as the connecting member 30 of the related art having the structure of FIG. 3.

As shown in FIG. 5, in the characteristic line 42 of the sample of the connecting member 30 of the related art, the probability of occurrence of the fatigue breakdown increases approximately linearly with the increase in the number of temperature cycles, and approximately saturates and reaches the maximum at the number of temperature cycles of 0.8 N. On the contrary, in the characteristic line 41 of the sample before the bending formation step having a small hardness variation, the probability of the fatigue breakdown is approximately unchanging, and is maintained at a low value up to 0.8 N.

A reason for the increase in the probability of occurrence of the fatigue breakdown for a larger hardness variation can be considered as follows. Of the elements forming the solar cell module 10, the solar cell 14 has the lowest thermal expansion coefficient, and also the thinnest thickness. On the other hand, the protective member 12 on the light receiving surface side has a thermal expansion coefficient which is about 5 times that of the solar cell 14, and has the thickest thickness and a Young's modulus close to a metal. The protective member 17 on the back surface side, the sealing members 13 and 16, and the adhesive have thermal expansion coefficients of values between the solar cell 14 and the protective member 12 on the light receiving surface side. Because the connecting members 15 and 30 are metal, these members have high thermal expansion coefficients, but these members have cross sectional areas which are less than or equal to 1/10 of those of the other members, and thus tend to be influenced by expansion and shrinkage of the other members. Therefore, while the solar cell 14 only changes the position slightly as a result of the temperature change, the protective member 12 on the light receiving surface side expands or shrinks significantly with the temperature change. The expansion or shrinkage is absorbed by the connecting member 15 or 30 having a small cross sectional area.

Therefore, when the solar cell module 10 is exposed to the temperature cycle test, the connecting member 15 or 30 repeatedly expands and shrinks. When the hardness distribution is uniform over the entire member as in the connecting member 15, the fatigue breakdown does not occur until the fatigue limit of the material itself is reached. On the other hand, when the hardness distribution is not uniform and there is a locally hard location such as the locations corresponding to the boundary regions B and C as in the connecting member 30, the stress is concentrated in these locations, and the member tends to be more easily broken down. For such a reason, it can be considered that the probability of occurrence of the fatigue breakdown becomes higher for the characteristic line 42 of the sample having a large variation of the hardness distribution.

In the preferred embodiment of the present invention, the hardness of the locations corresponding to the boundary regions B and C in the connecting member 15 is set to be less than or equal to 1.25 times the hardness of the flat portion 21 over the solar cells 14a and 14b. When an experiment was performed, it was seen that the probability of occurrence of the fatigue breakdown was reduced compared to the connecting member 30 of the related art. Furthermore, in the connecting member 15, the hardness of the locations corresponding to the boundary regions B and C is set at less than or equal to 1.1 times the hardness of the flat portion 21 over the solar cells 14a and 14b. When an experiment was performed, it was seen that the probability of occurrence of the fatigue breakdown was further reduced. Similarly, the hardness near the projection of the boundary region C was set at less than or equal to 1.1 times the hardness near the depression of the boundary region C. As a result of experiment, it was seen that the probability of occurrence of the fatigue breakdown was reduced compared to the connecting member 30 of the related art.

### EXPLANATION OF REFERENCE NUMERALS

10 SOLAR CELL MODULE; 12 PROTECTIVE MEMBER (ON LIGHT RECEIVING SURFACE SIDE); 13 SEALING MEMBER (ON LIGHT RECEIVING SURFACE SIDE); 14, 14a, 14b SOLAR CELL; 15, 30 CONNECTING MEMBER; 16 SEALING MEMBER (ON BACK SURFACE SIDE); 17 PROTECTIVE MEMBER (ON BACK SURFACE SIDE); 20, 21 FLAT PORTION; 22 INTERMEDIATE PORTION; 23 DIFFUSION SURFACE; 32, 33 TOOL; 34, 35, 36 MEASUREMENT POSITION; 41, 42 CHARACTERISTIC LINE.

What is claimed is:

1. A method for manufacturing a solar cell module, the solar cell comprising:
a plurality of solar cells;
a conductive connecting member that connects, of adjacent solar cells, a light receiving surface side of the solar cell on one side and a back surface side of the solar cell on the other side, the connecting member including a first flat portion, a second flat portion, and an intermediate portion connecting the first flat portion and the second flat portion; and
a protective member on the light receiving surface side and a protective member on the back surface side that are placed via a respective sealing member on the light receiving surface side and the back surface side, respectively, of the solar cells connected to each other by the connecting member, and
the method comprising:
after performing a thermal process on the connecting member, deforming the connecting member by pressurizing an entirety of the connecting member, so as to form the intermediate portion such that the hardness of the boundary region between the first flat portion or the second flat portion and the intermediate portion is less than or equal to 1.25 times the hardness of the first flat portion or the second flat portion; and
placing the first flat portion on the light receiving surface side of the solar cell on one side, and placing the second flat portion on the back surface side of the solar cell on the other side.

2. The solar cell module manufacturing method according to claim 1, further comprising:
forming the intermediate portion connecting the first flat portion and the second flat portion such that the hardness of the boundary region between the first flat portion or the second flat portion and the intermediate portion is less than or equal to 1.1 times the hardness of the first flat portion or the second flat portion.

3. The solar cell module manufacturing method according to claim 1, further comprising:
forming the connecting member to have a flat surface as a surface on one side, of surfaces on both sides overlapping in a thickness direction, and a diffusion surface that diffuse-reflects light as a surface on the other side.
